(19) United States
(12) Patent Application Publication
(10) Pub. No.: US 2014/0092577 A1
(43) Pub. Date: Apr. 3, 2014

(54) UNIT MOUNTING DEVICE, ELECTRONIC DEVICE SYSTEM, AND METHOD FOR MANUFACTURING UNIT MOUNTING DEVICE

(71) Applicants: Yoshikazu Murata, Chiyoda-ku (JP); Takashi Ando, Chiyoda-ku (JP)

(72) Inventors: Yoshikazu Murata, Chiyoda-ku (JP); Takashi Ando, Chiyoda-ku (JP)

(73) Assignee: MITSUBISHI ELECTRIC CORPORATION, Chiyoda-ku, Tokyo (JP)

(21) Appl. No.: 14/116,888

(22) PCT Filed: Jul. 29, 2011
(86) PCT No.: PCT/JP2011/067507

§ 371 Date: Nov. 11, 2013

(51) Int. Cl. H05K 7/02; B29C 47/00

(52) U.S. Cl. CPC H05K 7/02; B29C 47/004
USPC 361/809; 264/296

(57) ABSTRACT

A unit mounting device is a unit mounting device on which an electronic device unit 1 is mounted, and includes a base portion provided to face a side surface of the electronic device unit, an upper-side eaves portion formed to extend from an upper part of the base portion towards the electronic device unit side, a lower-side eaves portion formed to extend from a lower part of the base portion towards the electronic device unit side, a standing portion formed to project upward from an end part on an extending side of the lower-side eaves portion, and a projecting portion that is provided to have a width narrower than a width of the side surface of the electronic device unit and to project from the standing portion towards the electronic device unit side.

### FIELD

The present invention relates to a unit mounting device, an electronic device system, and a method for manufacturing a unit mounting device.

### BACKGROUND

Conventionally, an electronic device system in which electronic device units are mounted on a unit mounting device, which is constituted by a motherboard and a casing protecting the motherboard, has been used. In this type of electronic device system, the mounting operability of the electronic device units to the unit mounting device and maintaining of a stable mounting state of the electronic device units with respect to the unit mounting device while the system is in operation are required.

For example, Patent Literature 1 discloses a configuration in which electronic device units each having a concave groove portion are mounted on a unit mounting device, which is constituted by a casing including rail portions that each project from an eaves portion and have a convex cross section and a motherboard having connectors mounted thereon.

According to the configuration disclosed in Patent Literature 1, an electronic device unit is positioned in the horizontal direction by fitting the rail portion having a convex cross section on the unit mounting device side and the concave groove portion on the electronic device unit side to each other, and the electronic device unit is positioned in the vertical direction by the eaves portion on the unit mounting device side. Furthermore, the electronic device unit is retained by using separate components such as screws.

### Citation List

### Patent Literature

Patent Literature 1: Japanese Utility Model Laid-open Publication No. H03-6890

### SUMMARY

### Technical Problem

However, in the conventional configuration described above, because it is necessary to retain the electronic device unit by using separate components such as screws, there has been problems such as degradation of the mounting operability due to an increase in man-hours for mounting and cost increase of products due to an increase of the number of components.

The present invention has been achieved in view of the above, and an object of the present invention is to obtain a unit mounting device that can improve its mounting operability and can achieve cost reduction of products by reducing the number of components.

### Solution to Problem

In order to solve the above problems and achieve the object, the present invention is a unit mounting device on which an electronic device unit is mounted, and includes a base portion that is provided to face a side surface of the electronic device unit; an upper-side eaves portion that is formed to extend from an upper part of the base portion towards the electronic device unit side; a lower-side eaves portion that is formed to extend from a lower part of the base portion towards the electronic device unit side; a standing portion that is formed to project upward from an end part on an extending side of the lower-side eaves portion; and a projecting portion that is provided to have a width narrower than a width of the side surface of the electronic device unit and to project from the standing portion towards the electronic device unit side.

### Advantageous Effects of Invention

According to the present invention, the electronic device unit can be mounted on the unit mounting device by forming a fitting portion that is fitted in a standing portion and a projecting portion in the electronic device unit and by fitting the fitting portion in the standing portion and the projecting portion. Therefore, the mounting operability can be improved and cost reduction of products can be achieved by reducing the number of components.

### BRIEF DESCRIPTION OF DRAWINGS

FIG. 1 is an exploded perspective view of an electronic device system according to a first embodiment of the present invention.

FIG. 2 is a partial enlarged perspective view in which a portion A shown in FIG. 1 is enlarged.

FIG. 3 is a partial enlarged side view in which a lower-side eaves portion of a unit mounting device is enlarged.

FIG. 4 is a cross-sectional view taken along line B-B shown in FIG. 3.

FIG. 5 is a flowchart explaining a manufacturing procedure of the unit mounting device.

FIG. 6 is a partial enlarged perspective view of a lower part of the unit mounting device (a base structure) before performing press working.

FIG. 7 is a partial enlarged side view of a lower part of a unit mounting device according to a first modification of the first embodiment.

FIG. 8 is a partial enlarged side view of a lower part of a unit mounting device according to a second modification of the first embodiment.

FIG. 9 is a partial enlarged perspective view of a lower part of a unit mounting device as a comparative example.

FIG. 10 is a partial enlarged perspective view of the lower part of the unit mounting device shown in FIG. 9, depicting a state (a state of a base structure) before performing press working.

FIG. 11 is a partial enlarged side view of the lower part of the unit mounting device shown in FIG. 9.

### DESCRIPTION OF EMBODIMENTS

Exemplary embodiments of a unit mounting device, an electronic device system, and a method for manufacturing a unit mounting device according to the present invention will be explained below in detail with reference to the accompanying drawings. The present invention is not limited to the embodiments.

First embodiment.

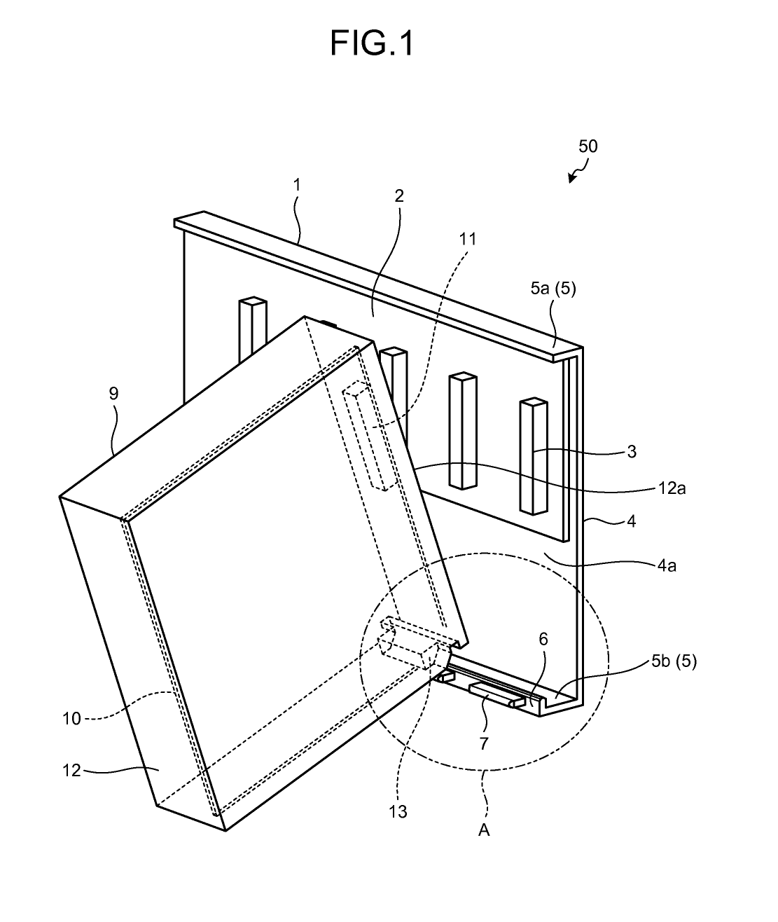

FIG. 1 is an exploded perspective view of an electronic device system according to a first embodiment of the present invention. An electronic device system 50 is constituted by mounting an electronic device unit 9 on a unit mounting device 1. The electronic device unit 9 is constituted by accommodating a board 10 in an electronic-device-unit casing 12.

The electronic-device-unit casing 12 constitutes an outer frame of the electronic device unit 9. The electronic device unit 9 is mounted on the unit mounting device 1 in a state where a side surface 12a of the electronic-device-unit casing 12 faces the unit mounting device 1. An electronic-device-unit fitting portion 13 is formed in the electronic-device-unit casing 12. The electronic-device-unit fitting portion 13 is explained later in detail.

An electronic-device-unit connector 11 is mounted on the board 10. The electronic-device-unit connector 11 is exposed to the side surface 12a side in a state where the board 10 is accommodated in the electronic-device-unit casing 12.

The unit mounting device 1 is configured to include a unit-mounting-device casing 4 and a motherboard 2. The unit-mounting-device casing 4 includes a base portion 4a that faces the side surface 12a of the electronic device unit 9 and an eaves portion 5 that is formed on the top and bottom of the base portion 4a.

The eaves portion 5 is constituted by an upper-side eaves portion 5a that extends from an upper part of the base portion 4a towards the electronic device unit 9 side, and a lower-side eaves portion 5b that extends from a lower part of the base portion 4a towards the electronic device unit 9 side. In a state where the electronic device unit 9 is mounted on the unit mounting device 1, the electronic device unit 9 is in a state where its top and bottom portions that are closer to the side surface 12a are sandwiched by the eaves portion 5 (the upper-side eaves portion 5a and the lower-side eaves portion 5b).

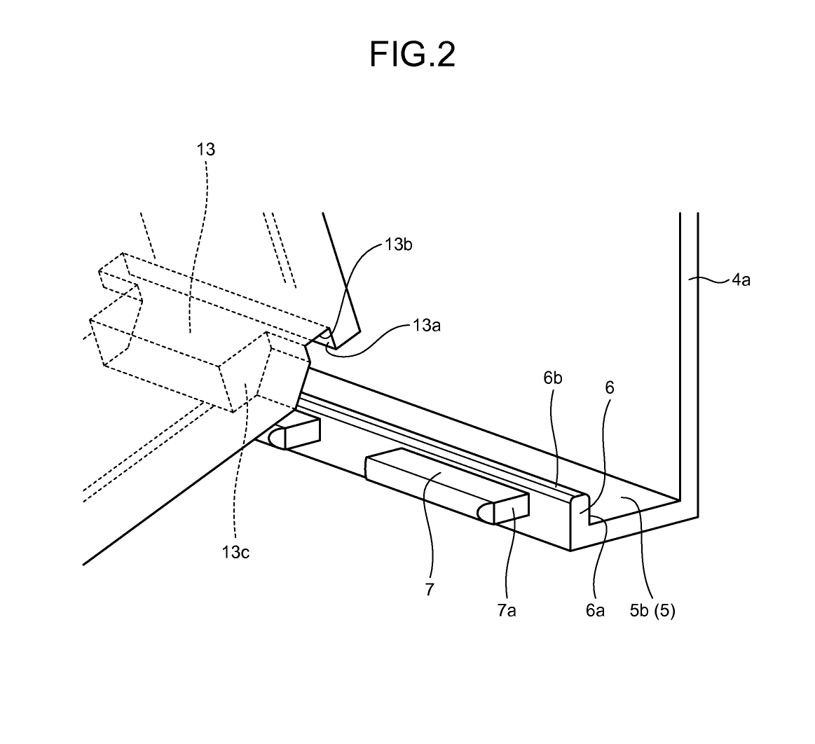

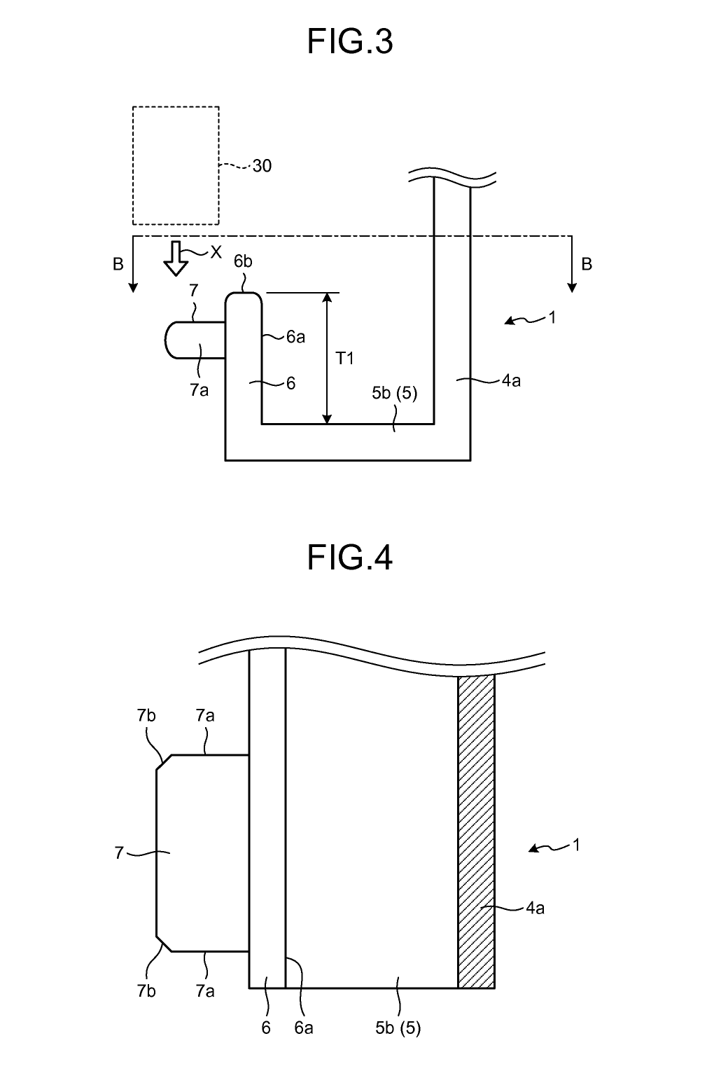

FIG. 2 is a partial enlarged perspective view in which a portion A shown in FIG. 1 is enlarged. FIG. 3 is a partial enlarged side view in which the lower-side eaves portion 5b of the unit mounting device 1 is enlarged. FIG. 4 is a cross-sectional view taken along line B-B shown in FIG. 3.

As shown in FIGS. 2 to 4, a standing portion 6 and projecting portions 7 are arranged in a lower part of the unit mounting device 1. The standing portion 6 is formed to project upward from an end part on an extending side of the lower-side eaves portion 5b.

As a part of the electronic-device-unit fitting portion 13, a groove that fits the standing portion 6 is formed in the electronic-device-unit casing 12 of the electronic device unit 9. By fitting the electronic-device-unit fitting portion 13 in the standing portion 6, a retaining surface 6a of the standing portion 6 and a fitting-portion rear surface 13a of the electronic-device-unit fitting portion 13 come into contact with each other, thereby preventing falling off of the electronic device unit 9.

By fitting the electronic-device-unit fitting portion 13 in the standing portion 6, a lower-side positioning surface 6b, which is an upper surface of the standing portion 6, and a fitting-portion lower surface 13b of the electronic-device-unit fitting portion 13 come into contact with each other, thereby positioning the electronic device unit 9 in the vertical direction.

The standing portion 6 is formed to have a width wider than that of the projecting portion 7, which is described later, and in the present embodiment, the standing portion 6 is formed over the entire horizontal width of the unit-mounting-device casing 4. With this configuration, the lower-side positioning surface 6b of the standing portion 6 can support the entire horizontal width of the electronic device unit 9, thereby suppressing shaking of the electronic device unit 9 in the horizontal direction.

The projecting portion 7 is formed to have a width narrower than the width of the side surface 12a of the electronic device unit 9, and the projecting portion 7 is arranged to project from the standing portion 6 towards the electronic device unit 9 side. As shown in FIG. 3, the projecting portion 7 is arranged in a middle part in the height direction of the standing portion 6.

As a part of the electronic-device-unit fitting portion 13, a concave part in which the projecting portion 7 is fitted is formed in the electronic-device-unit casing 12 of the electronic device unit 9. The concave part is formed to have a width substantially equal to that of the projecting portion 7. Accordingly, by fitting the electronic-device-unit fitting portion 13 in the projecting portion 7, a horizontal positioning surface 7a of the projecting portion 7 and a fitting-portion side surface 13c of the electronic-device-unit fitting portion 13 come into contact with each other, thereby positioning the electronic device unit 9 in the horizontal direction.

The corner of an upper surface side of the standing portion 6b and the corner of a projecting side of the projecting portion 7 are chamfered. The types of chamfering include square chamfering like the corner of the projecting side of the projecting portion 7 shown in FIG. 4 and round chamfering like the upper surface of the standing portion 6 shown in FIG. 3. By performing chamfering in this manner, it is possible to prevent the electronic-device-unit fitting portion 13 from being stuck at the time of mounting the electronic device unit 9, thereby enabling smooth mounting of the electronic device unit 9. Furthermore, by preventing the electronic-device-unit fitting portion 13 from being stuck, it is possible to suppress damages on the electronic-device-unit fitting portion 13 and the unit mounting device 1.

The motherboard 2 is mounted on the base portion 4a of the unit-mounting-device casing 4 and faces the side surface 12a of the electronic device unit 9. Unit-mounting-device connectors 3 are arranged on the motherboard 2. When the electronic device unit 9 is mounted on the unit mounting device 1, the electronic-device-unit connector 11 arranged in the electronic device unit 9 and the unit-mounting-device connector 3 arranged in the unit mounting device I are connected to each other.

As described above, by fitting the electronic-device-unit fitting portion 13 in the standing portion 6 and the projecting portion 7 that are arranged in the lower-side eaves portion 5b at the time of mounting the electronic device unit 9 on the unit mounting device 1, positioning in the vertical direction, positioning in the horizontal direction, and prevention of falling off of the electronic device unit 9 can be achieved, and thus it becomes possible to omit a work of fixing the electronic device unit 9 using separate components such as screws.

Therefore, the mounting operability of the electronic device unit 9 can be improved and cost reduction of products can be achieved by reducing the number of components.

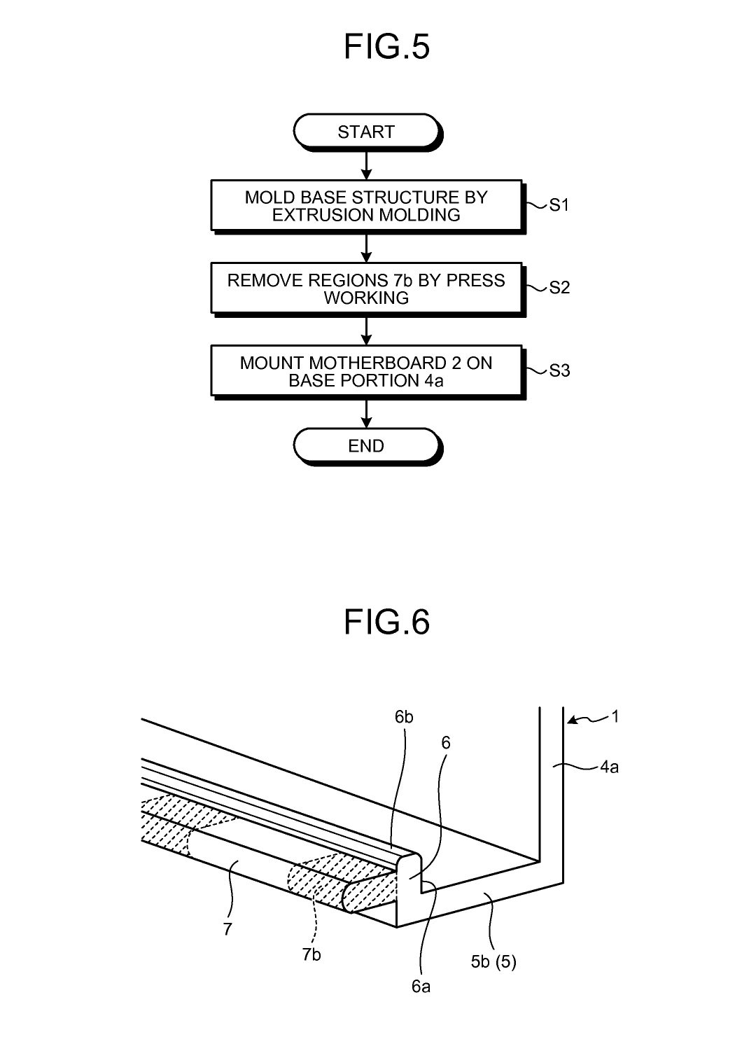

A manufacturing method of the unit mounting device 1 is explained next. FIG. 5 is a flowchart explaining a manufacturing procedure of the unit mounting device 1. First, a base structure including the base portion 4a, the upper-side eaves portion 5a, the lower-side eaves portion 5b, the standing portion 6, and the projecting portion 7 is molded by extrusion molding (Step S1).

FIG. 6 is a partial enlarged perspective view of a lower part of the unit mounting device (a base structure) before performing press working. As shown in FIG. 6, in the base structure molded by extrusion molding, the projecting portion 7 is formed over the entire horizontal width of the base structure, and the width of the projecting portion 7 is not narrower than the width of the side surface 12a of the electronic device unit 9.

That is, in order to form the horizontal positioning unit 7a as the projecting portion 7 as shown in FIG. 2, it is necessary to remove regions 7b, which are hatched by broken lines in FIG. 6. Accordingly, the regions 7b are removed (Step S2) by performing press working with a press mold 30 (see FIG. 3). Thereafter, the motherboard 2 is mounted on the base portion 4a (Step S3), thereby manufacturing the unit mounting device 1.

As shown in FIG. 3, press working is performed while moving the press mold 30 in the direction indicated by an arrow X. At this time, the press mold 30 performs press working only on the projecting portion 7, and the standing portion 6 is left without being subjected to press working.

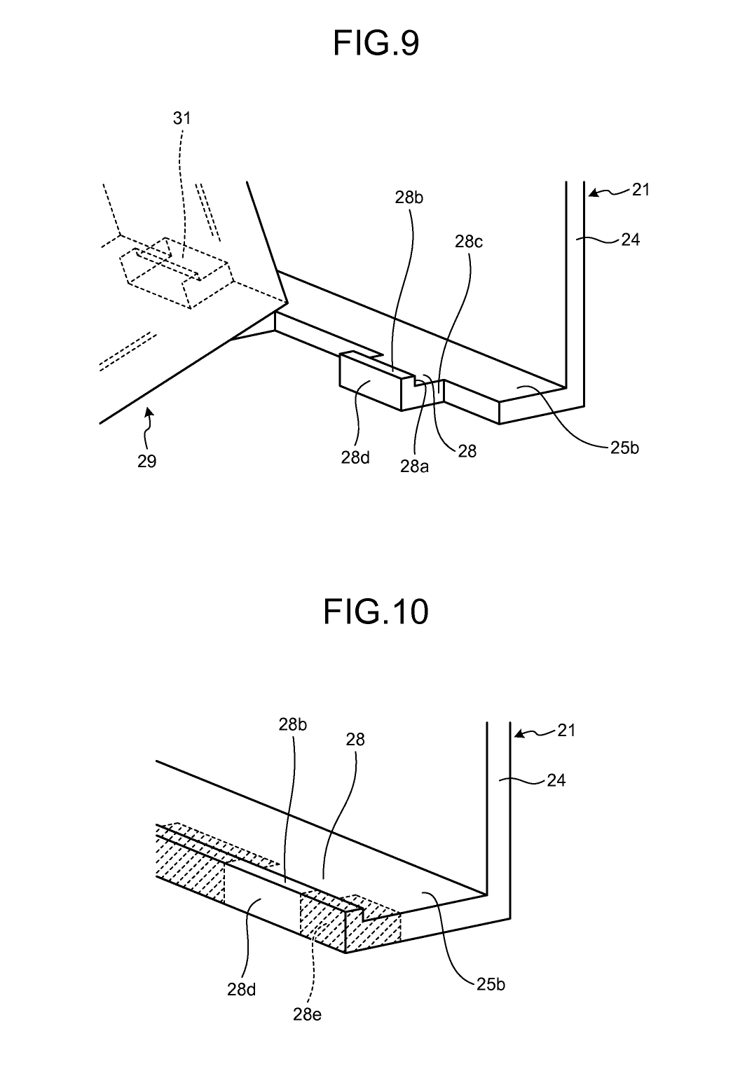

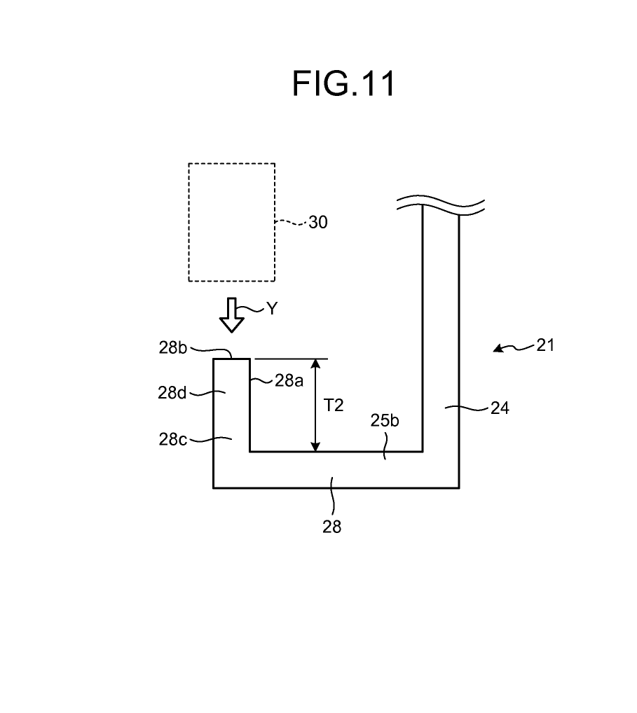

A unit mounting device as a comparative example is explained below. FIG. 9 is a partial enlarged perspective view of a lower part of the unit mounting device as the comparative example. FIG. 10 is a partial enlarged perspective view of the lower part of the unit mounting device shown in FIG. 9, depicting a state (a state of a base structure) before performing press working. FIG. 11 is a partial enlarged side view of the lower part of the unit mounting device shown in FIG. 9. Conventionally, there has been a case where a unit mounting device 21 illustrated as the comparative example is used.

As shown in FIG. 9, in the unit mounting device 21 as the comparative example, projecting portions 28, which project from a lower-side eaves portion 25b of a unit-mounting-device casing 24 towards an electronic device unit 29 side, are formed. The projecting portion 28 is formed to have a width narrower than that of the electronic device unit 29, and a side surface thereof functions as a horizontal positioning surface 28c.

The projecting portion 28 is such that the end part thereof on a projecting side is formed into a standing portion 28d provided to stand upward. The standing portion 28d includes a retaining surface 28a, which prevents falling off of the electronic device unit 24 with the retaining surface 28a being fitted in an electronic-device-unit fitting portion 31 that is formed in the electronic device unit 29, and a lower-side positioning surface 28b, which supports the electronic device unit 29 from its bottom side to position the electronic device unit 29 in the vertical direction.

Similarly to the projecting portion 28, the standing portion 28d formed on an end part of the projecting portion 28 is formed to have a width narrower than that of the electronic device unit 9. Therefore, supporting of the electronic device unit 9 by the lower-side positioning surface 28b becomes unstable, and thus it is difficult to suppress shaking of the electronic device unit 29 in the horizontal direction. Furthermore, if the electronic device unit 29 shakes, the connectors 3 and 11 (see also FIG. 1) may be damaged.

In contrast, in the present embodiment, as described above, because the lower-side positioning surface 6b can support the electronic device unit 9 over the entire horizontal width, shaking of the electronic device unit 9 in the horizontal direction can be suppressed. Therefore, damages on the connectors 3 and 11 can be suppressed, thereby achieving improvement of the reliability of the electronic device system 50.

As shown in FIG. 10, when regions 28e are removed from a base structure by press working, the press mold 30 needs to be moved in the direction indicated by an arrow Y as shown in FIG. 11. At this time, the standing portion 28d as well as the projecting portion 28 is subjected to press working by the press mold 30.

Therefore, when a standing height T2 of the standing portion 28d is set high, at the time of press working, a load is applied to the lower-side eaves portion 25b and the projecting portion 28, and the lower-side eaves portion 25b and the projecting portion 28 may be deformed. Furthermore, when the standing height T2 of the standing portion 28d is set low so as to prevent deformation of the lower-side eaves portion 25b and the projecting portion 28, the retaining surface 28a becomes lower, and this causes a tendency that the electronic device unit 29 easily falls off from the projecting portion 28.

In contrast, according to the unit mounting device 1 of the present embodiment, as shown in FIG. 3, the projecting portions 7 can be formed without performing press working on the standing portion 6. Accordingly, it is possible to suppress deformation of the lower-side eaves portion 5b due to press working. Furthermore, even when a standing height T1 of the standing portion 6 is set high, at the time of press working, any load is hardly applied to the lower-side eaves portion 5b. Accordingly, as compared to the comparative example, the standing height T1 of the standing portion 6 can be set higher. With setting the standing height T1 of the standing portion 6 higher, the retaining surface 6a is formed larger so as to more securely prevent falling off of the electronic device unit 9.

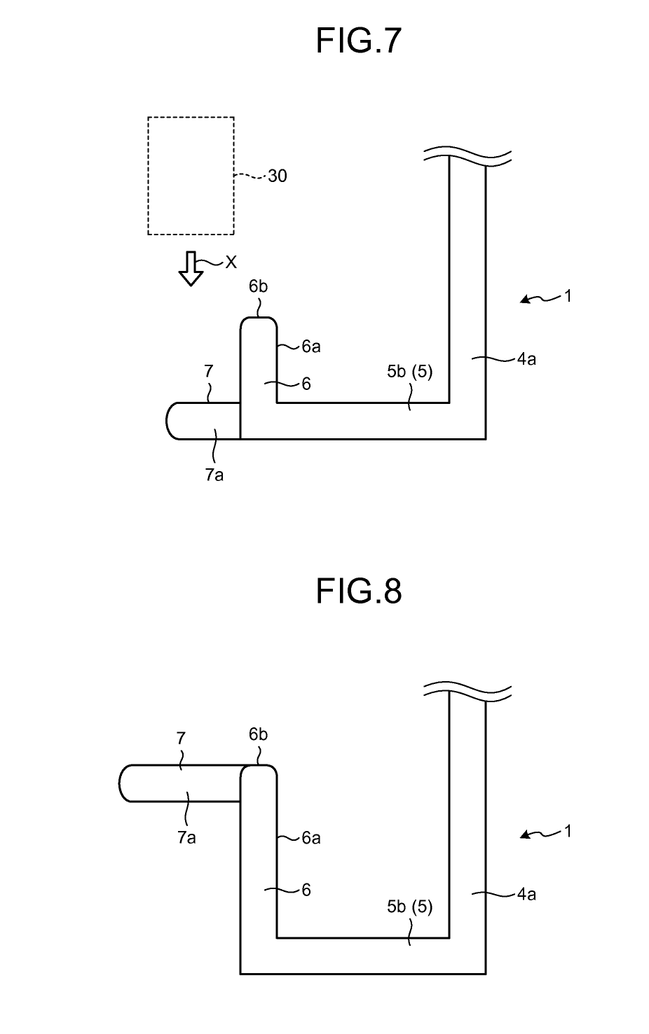

FIG. 7 is a partial enlarged side view of a lower part of a unit mounting device according to a first modification of the first embodiment. As shown in FIG. 7, the projecting portions 7 may be formed at a lower end part of the standing portion 6 in the height direction. Even with this configuration, the projecting portions 7 can be formed without performing press working on the standing portion 6. Accordingly, similarly to the example described above, deformation of the lower-side eaves portion 5b can be suppressed, and with forming the retaining surface 6a larger, it is possible to more securely prevent falling off of the electronic device unit.

FIG. 8 is a partial enlarged side view of a lower part of a unit mounting device according to a second modification of the first embodiment. As shown in FIG. 8, the projecting portions 7 may be formed at a lower end part of the standing portion 6 in the height direction. Even with this configuration, the projecting portions 7 can be formed without performing press working on the standing portion 6. Accordingly, similarly to the example described above, deformation of the lower-side eaves portion 5b can be suppressed, and with forming the retaining surface 6a larger, it is possible to more securely prevent falling off of the electronic device unit.

### INDUSTRIAL APPLICABILITY

As described above, the unit mounting device according to the present invention is useful as a unit mounting device on which an electronic device unit is mounted.

### REFERENCE SIGNS LIST

1 unit mounting device

2 motherboard

3 unit-mounting-device connector

4 unit-mounting-device casing

4a base portion

5 eaves portion

5a upper-side eaves portion

5b lower-side eaves portion

6 standing portion

6a retaining surface

6b lower-side positioning surface

7 projecting portion

7a horizontal positioning surface

7b region

9 electronic device unit

10 board

11 electronic-device-unit connector

12 electronic-device-unit casing

12a side surface

13 electronic-device-unit fitting portion

13a fitting-portion rear surface

13b fitting-portion lower surface

13c fitting-portion side surface

21 unit mounting device

24 unit-mounting-device casing

25b lower-side eaves portion

28 projecting portion

28a retaining surface

28b lower-side positioning surface

28c horizontal positioning surface

28d standing portion

28e region

29 electronic device unit

30 press mold

31 electronic-device-unit fitting portion

50 electronic device system

X,Y arrow

1. A unit mounting device on which an electronic device unit is mounted, the unit mounting device comprising:
a base portion that is provided to face a side surface of the electronic device unit;
an upper-side eaves portion that is formed to extend from an upper part of the base portion towards the electronic device unit side;
a lower-side eaves portion that is formed to extend from a lower part of the base portion towards the electronic device unit side;
a standing portion that is formed to project upward from an end part on an extending side of the lower-side eaves portion; and
a projecting portion that is provided to have a width narrower than a width of the side surface of the electronic device unit and to project from the standing portion towards the electronic device unit side.

2. The unit mounting device according to claim 1, wherein the standing portion is formed to have a width wider than a width of the projecting portion.

3. The unit mounting device according to claim 1, wherein a corner of an upper surface of the standing portion and a corner of a surface on a projecting side of the projecting portion are chamfered.

4. An electronic device system comprising:
the unit mounting device according to claim 1; and
an electronic device unit in which a fitting portion that fits in the standing portion and the projecting portion is formed.

5. A method for manufacturing a unit mounting device on which an electronic device unit is mounted, the method comprising:
molding a base structure by extrusion molding, where the base structure including a base portion that is provided to face a side surface of the electronic device unit, an upper-side eaves portion that is formed to extend from an upper part of the base portion towards the electronic device unit side, a lower-side eaves portion that is formed to extend from a lower part of the base portion towards the electronic device unit side, a standing portion that is formed to project upward from the lower-side eaves portion, and a projecting portion that is formed to project from the standing portion towards the electronic device unit side; and
forming the projecting portion by press molding to have a width narrower than a width of the side surface.
